(19) United States
(12) Patent Application Publication
(10) Pub. No.: US 2026/0206596 A1
(43) Pub. Date: Jul. 16, 2026

(54) SEMICONDUCTOR DEVICES INCLUDING INSULATING STRUCTURE

(71) Applicant: SAMSUNG ELECTRONICS CO., LTD., Suwon-si (KR)

(72) Inventors: Junhyung KIM, Suwon-si (KR); Joongwon SHIN, Suwon-si (KR); Hyoungjun KIM, Suwon-si (KR); Jongmin LEE, Suwon-si (KR); Ilwoo JUNG, Suwon-si (KR)

(73) Assignee: SAMSUNG ELECTRONICS CO., LTD., Suwon-si (KR)

(21) Appl. No.: 19/432,752

(22) Filed: Dec. 24, 2025

(30) Foreign Application Priority Data
Jan. 15, 2025 (KR) 10-2025-0006217

(51) Int. Cl. H10W 42/00; H10B 80/00; H10W 20/20; H10W 20/42; H10W 90/00; H10W 90/20

(52) U.S. Cl. CPC H10W 42/121; H10B 80/00; H10W 20/2134; H10W 20/42; H10W 90/291; H10W 90/297; H10W 90/722

(57) ABSTRACT

A lower structure of a semiconductor device includes a semiconductor substrate including a chip region, and an edge region of at least one side of the chip region; an interconnection structure disposed on the semiconductor substrate, and including a plurality of interconnection pattern layers and an insulating layer covering the plurality of interconnection pattern layers; a first insulating structure on the interconnection structure; a lower conductive pattern on the first insulating structure; and a second insulating structure on the lower conductive pattern. An upper structure is on the lower structure and includes an upper conductive pattern on the second insulating structure. The first insulating structure includes a first insulating portion and a second insulating portion. At least a portion of a side surface of the lower structure is defined by the second side of the second insulating portion.

### CROSS-REFERENCE TO RELATED APPLICATION(S

This application claims the benefit under 35 USC 119(a) of Korean Patent Application No. 10-2025-0006217 filed on January 15, 2025 in the Korean Intellectual Property Office, the entire disclosure of which is incorporated herein by reference for all purposes.

### BACKGROUND

The present inventive concept relates to semiconductor devices and semiconductor packages including the same.

Demand for performance and stability of semiconductor devices is increasing. In addition, the performance and stability of semiconductor devices mounted in semiconductor packages are required. Various technologies are required to manufacture semiconductor devices that respond to performance and stability trends. In particular, the need for technologies to improve the reliability of semiconductor devices is required.

### SUMMARY

Example embodiments provide a semiconductor device with improved reliability and a semiconductor package including the same.

According to example embodiments, a semiconductor device includes a lower structure; and an upper structure on the lower structure. The lower structure includes a semiconductor substrate including a chip region, and an edge region of at least one side of the chip region; an interconnection structure disposed on the semiconductor substrate, and including a plurality of interconnection pattern layers and an insulating layer covering the plurality of interconnection pattern layers; a first insulating structure on the interconnection structure; a lower conductive pattern on the first insulating structure; and a second insulating structure on the lower conductive pattern. The upper structure includes an upper conductive pattern on the second insulating structure; and a passivation structure having an opening exposing at least a portion of the upper conductive pattern, on the second insulating structure. The first insulating structure includes a first insulating portion including a first portion disposed on an upper surface of the interconnection structure in the chip region and a second portion extending from the first portion in a horizontal direction and disposed in the edge region; and

a second insulating portion extending downwardly from the second portion of the first insulating portion in the edge region. The second insulating portion has a first side covering a side surface of the interconnection structure and a second side opposite to the first side. At least a portion of a side surface of the lower structure is defined by the second side of the second insulating portion.

According to example embodiments, a semiconductor device includes a semiconductor substrate including a device region, a buffer region surrounding the device region, and an edge region surrounding the buffer region; an interconnection structure disposed on the semiconductor substrate and including a plurality of interconnection pattern layers, the interconnection structure having a side surface defined between the buffer region and the edge region; a first insulating structure on the interconnection structure, the first insulating structure including a first insulating portion including a portion extending in a first direction along an upper surface of the interconnection structure, in the device region, the buffer region, and the edge region, and a second insulating portion extending downwardly from the first insulating portion and covering the side surface of the interconnection structure, in the edge region; a lower conductive pattern on the first insulating structure; a second insulating structure on the lower conductive pattern; a first conductive via penetrating the first insulating structure and connecting at least a portion of the plurality of interconnection pattern layers and the lower conductive pattern; an upper conductive pattern on the second insulating structure; and a second conductive via penetrating the second insulating structure and connecting the lower conductive pattern and the upper conductive pattern.

According to example embodiments, a semiconductor device includes a lower structure; and an upper structure on the lower structure. The lower structure includes a semiconductor substrate including a device region, a buffer region surrounding the device region, and an edge region surrounding the buffer region; a device layer on the semiconductor substrate; an interconnection structure disposed on the device layer and including a plurality of interconnection pattern layers and an insulating layer covering the plurality of interconnection pattern layers, the interconnection structure having a side surface defined between the buffer region and the edge region; a first insulating structure on the interconnection structure; a lower conductive pattern disposed on the first insulating structure; and a second insulating structure on the lower conductive pattern. The upper structure includes an upper conductive pattern on the second insulating structure; and a passivation structure covering the upper conductive

pattern, on the second insulating structure, and having an opening exposing at least a portion of the upper conductive pattern. The first insulating structure includes a first insulating portion including a portion disposed above the interconnection structure, in the device region and the buffer region; and a second insulating portion extending downwardly from at least a portion of the first insulating portion and covering the side surface of the interconnection structure, a lower end of the second insulating portion extending into the device layer. At least a portion of a side surface of the lower structure is defined by a side surface of the first insulating structure and a side surface of the second insulating structure aligned with each other.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor substrate including a semiconductor device according to an example embodiment.

FIG. 2 is a partial enlarged view of FIG. 1.

FIGS. 3 to 12 are vertical cross-sectional views of a semiconductor substrate illustrated in a process sequence to illustrate a method of manufacturing a semiconductor device according to an example embodiment.

FIG. 13 is a partial enlarged view of a semiconductor device illustrated in FIG. 12.

FIGS. 14 and 15 are vertical cross-sectional views of semiconductor devices according to example embodiments.

FIG. 16 is a vertical cross-sectional view of a semiconductor device according to example embodiments.

FIG. 17 is a vertical cross-sectional view of a semiconductor package including a semiconductor device according to example embodiments.

FIG. 18 is a partial enlarged view of the semiconductor package illustrated in FIG. 17.

FIG. 19 is a vertical cross-sectional view of a semiconductor package including a semiconductor device according to example embodiments.

### DETAILED DESCRIPTION

Hereinafter, terms such as “on,” “upper,” “upper surface,” “below,” “lower,” “low

surface,” “side,” “side surface,” “top,” “bottom,” and the like are understood to refer to the drawings, except in cases where they are separately referred to by being indicated with drawing symbols. Terms such as “upper,” “middle,” “intermediate," and “lower” may also be replaced with other terms, such as “first,” “second,” and “third,” and used to describe components of the specification. Terms such as “first,” “second,” and “third” may be used to describe various components, but the components are not limited by the terms, and a “first component” may be named a “second component.”

Hereinafter, example embodiments will be described with reference to the attached drawings.

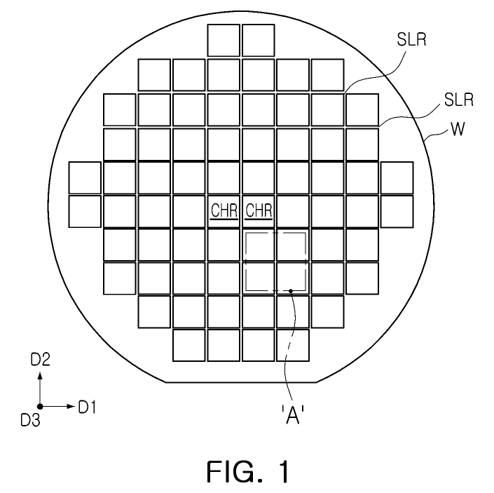

FIG. 1 is a plan view of a semiconductor substrate including a semiconductor device according to an example embodiment.

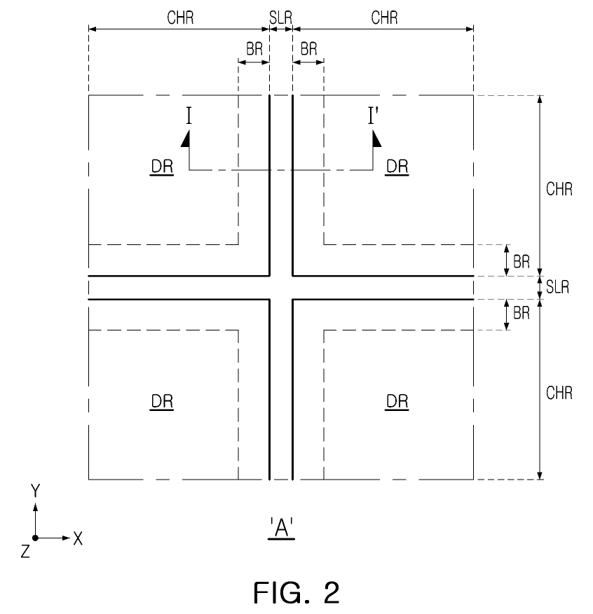

FIG. 2 is a partially enlarged view of FIG. 1.

Referring to FIG. 1 and FIG. 2, the semiconductor substrate (W) may include chip regions (CHR) and scribe line regions (SLR) between the chip regions (CHR).

The chip regions (CHR) may include a device region (DR) in which integrated circuit elements (112) are disposed and a buffer region (BR) in which a guard ring (140) is disposed surrounding the device region (DR).

The scribe line regions (SLR) may extend in a first horizontal direction (e.g., D1 direction) and a second horizontal direction (e.g., D2 direction) intersecting the first horizontal direction. The chip regions (CHR) may be disposed to be spaced apart from each other in the first horizontal direction and the second horizontal direction, and may be surrounded by the scribe line regions (SLR).

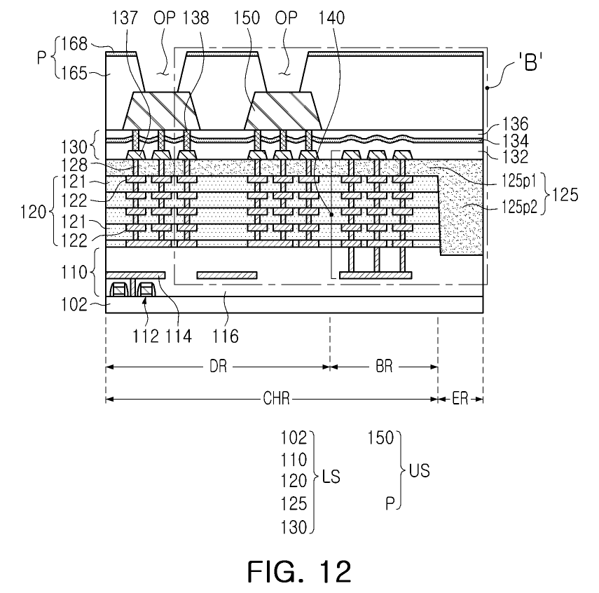

The semiconductor device (100) may be formed by separating chip regions (CHR) along a scribe line region (SLR) by the dicing process described below. By the dicing process, the scribe line region (SLR) may be defined by separating into a plurality of edge regions (ER) (see FIG. 12).

In an example embodiment, the device region (DR) may be provided with a volatile memory device such as a Dynamic Random Access Memory (DRAM) or a Static Random Access Memory (SRAM), or a nonvolatile memory device such as a Phase-change Random Access Memory (PRAM), a Magnetoresistive Random Access Memory (MRAM), a Ferroelectric Random Access Memory (FeRAM), or a Resistive Random Access Memory (RRAM). In an example embodiment, the device region (DR) may be provided with a logic device such as a microprocessor, an analog device, or a digital signal processor.

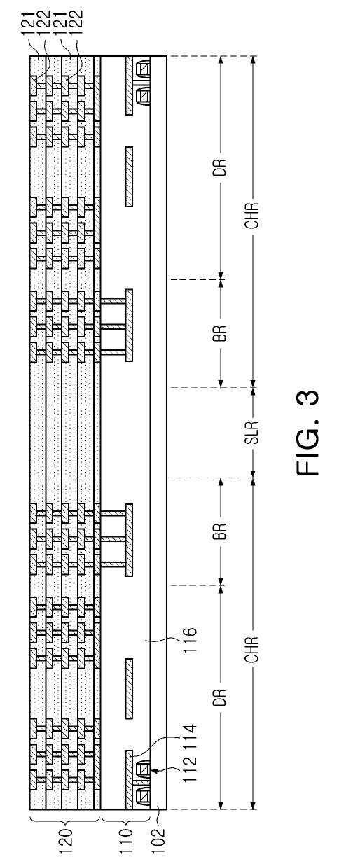

FIGS. 3 to 12 are vertical cross-sectional views of a semiconductor substrate illustrated according to a process sequence to illustrate a method of manufacturing a semiconductor device (100) according to an example embodiment.

Referring to FIG. 3, a device layer (110) and an interconnection structure (120) may be formed on a semiconductor substrate (102). The semiconductor substrate (102) may correspond to the semiconductor substrate (W) illustrated in FIG. 1.

The semiconductor substrate (102) may include chip regions (CHR) and a scribe line region (SLR) between the chip regions (CHR). The chip region (CHR) may include a device region (DR) and a buffer region (BR). The buffer region (BR) may surround the device region (DR). The semiconductor substrate (102) may include a semiconductor material. For example, the semiconductor substrate (102) may be a silicon substrate, a germanium substrate, a silicon germanium substrate, or an SOI (silicon on insulator) substrate. The semiconductor substrate (102) may include a semiconductor material such as a group IV semiconductor, a group III-V compound semiconductor, or a group II-VI compound semiconductor.

The device layer (110) may include integrated circuit elements (112), internal interconnections (114), and a lower interlayer insulating layer (116). The integrated circuit elements (112) may include a memory cell array including switching elements and data storage elements, and logic elements including MOSFETs, capacitors, and resistors. The internal interconnection (114) may be disposed on the integrated circuit elements (112) and may be electrically connected to at least one of the integrated circuit elements (112). The integrated circuit elements (112) may be disposed in a device region (DR). The internal interconnection (114) may be disposed in the device region (DR) and the buffer region (BR), and in some embodiments, the internal interconnection (114) may also be disposed in a scribe line region (SLR). The lower interlayer insulating layer (116) may cover the semiconductor substrate (102), the integrated circuit elements (112), and the internal interconnections (114). The internal interconnections (114) may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the internal interconnections (114) may include copper (Cu). The lower interlayer insulating layer (116) may include silicon oxide, silicon nitride, silicon oxynitride, or combinations thereof. For example, the lower interlayer insulating layer (116) may include silicon oxide.

The interconnection structure (120) may be formed on the device layer (110). The interconnection structure (120) may include interlayer insulating layers (121) and a plurality of interconnection pattern layers (122). The interlayer insulating layers (121) may be sequentially deposited on the lower interlayer insulating layer (116). The plurality of interconnection pattern layers (122) may be disposed in a chip region (CHR) and may be embedded within the interlayer insulating layers (121). At least one of the plurality of interconnection pattern layers (122) may be electrically connected to the integrated circuit element (112). The plurality of interconnection pattern layers (122) may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the plurality of interconnection pattern layers (122) may include copper (Cu).

The interlayer insulating layer (121) may include a low-κ dielectric material having a low dielectric constant. For example, the interlayer insulating layer (121) may include silicon oxide or an organic polymer doped with impurities. In an example embodiment, the interlayer insulating layer (121) may include SiOCH, SiCN, or a combination thereof.

The plurality of interconnection pattern layers (122) may include copper (Cu), aluminum (Al), tungsten (W), nickel (Ni), titanium (Ti), titanium nitride (TiN), tantalum (Ta), tantalum nitride (TaN), gold (Au), or combinations thereof. At least some of the plurality of interconnection pattern layers (122) may include a plurality of patterns spaced apart in the horizontal direction. In the present specification, the ‘pattern layer’ may be understood to collectively refer to ‘patterns’ disposed at the same level. The ‘patterns’ may include wiring extending in the horizontal direction and pads connected to the wiring. At least some of the plurality of interconnection pattern layers (122) may be vertically connected via vias. The plurality of interconnection pattern layers (122) may be formed of a plurality of layers. For example, the plurality of interconnection pattern layers (122) may be formed of five layers, but is not limited thereto. The plurality of interconnection pattern layers (122) may be formed of, for example, six layers, seven layers, or more layers.

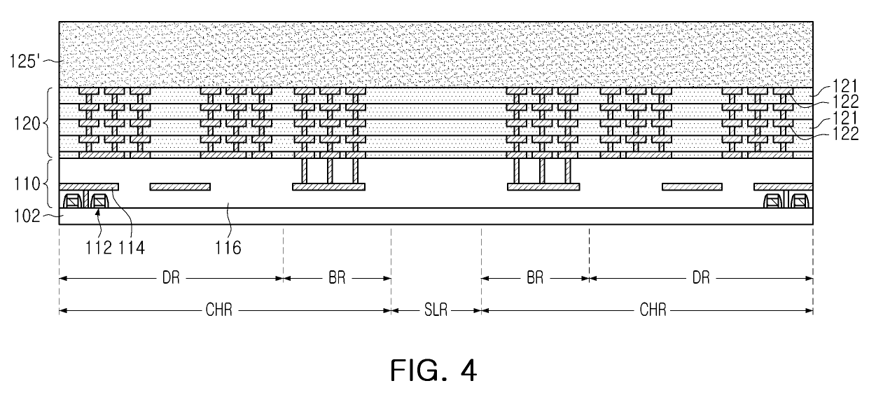

Referring to FIG. 4, an insulating material layer (125’) may be formed on the interconnection structure (120).

An insulating material layer (125’) may be conformally formed on the interconnection structure (120) of the chip region (CHR) and the scribe line region (SLR). The insulating material layer (125’) may include silicon oxide. For example, the insulating material layer (125’) may include TetraEthyl OrthoSilicate (TEOS).

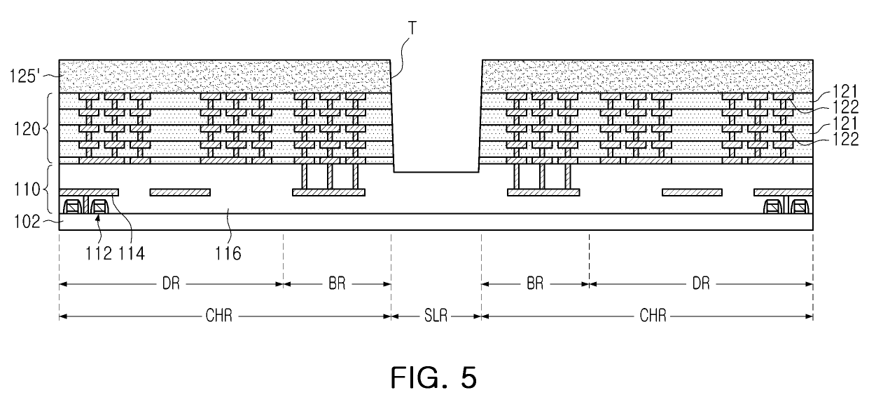

Referring to FIG. 5, a trench (T) extending downwardly through the insulating material layer (125’) and the interconnection structure (120) may be formed.

A trench (T) extending vertically through the insulating material layer (125’) and the interconnection structure (120) of the scribe line region (SLR) may be formed. The width of the trench (T) may decrease in a direction toward the upper surface of the semiconductor substrate (102). The trench (T) may penetrate a portion of the upper region of the device layer (110), but is not limited thereto. For example, the trench (T) may expose the upper surface of the device layer (110) without penetrating the device layer (110).

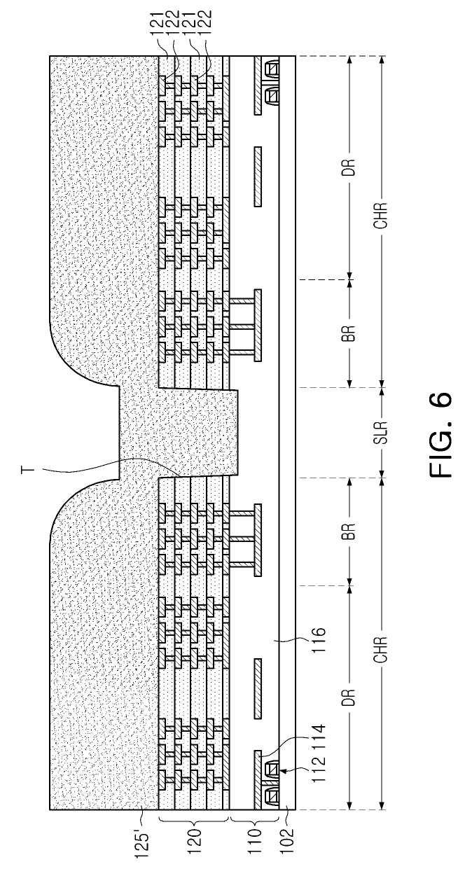

Referring to FIG. 6, an insulating material layer (125’) filling the trench (T) may be formed.

The insulating material layer (125’) filling the trench (T) may be formed on the interconnection structure (120). The insulating material layer (125’) described with reference to FIG. 6 may include substantially the same material as the insulating material layer (125’) described with reference to FIG. 4. The insulating material layer (125’) described with reference to FIG. 6 may include silicon oxide, for example, TetraEthyl OrthoSilicate (TEOS).

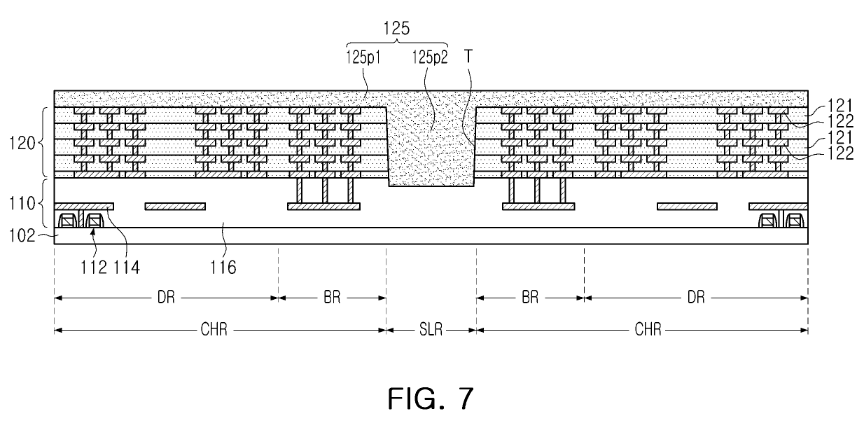

Referring to FIG. 7, a planarization process may be performed on the insulating material layer (125’) to form a first insulating structure (125).

By the planarization process, a first insulating structure (125) having an upper surface substantially parallel to an upper surface of a semiconductor substrate (102) may be formed. In this case, the planarization process may include a chemical mechanical polishing (CMP) process.

The first insulating structure (125) may include a first insulating portion (125p1) extending horizontally on the interconnection structure (120) and a second insulating portion (125p2) extending downwardly from the first insulating portion (125p1) of the scribe line region (SLR) to fill a trench (T). The thickness of the first insulating structure (125) may be greater than the thickness of the interconnection structure (120). For example, the thickness of the second insulating portion (125p2) of the first insulating structure (125) may be greater than the thickness of the interconnection structure (120). The thickness of the first insulating portion (125p1) of the first insulating structure (125) may be larger than the thickness of the interlayer insulating layer (121), but is not limited thereto. The thicknesses of the first insulating portion (125p1) and the interlayer insulating layer (121) may be, for example, substantially the same.

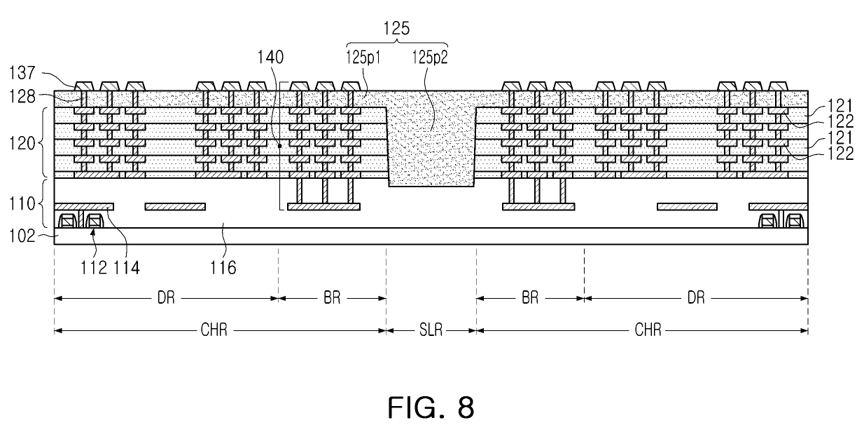

Referring to FIG. 8, a first conductive via (128) and a lower conductive pattern (137) may be formed.

An opening is formed to penetrate the first insulating portion (125p1) on the device region (DR) and the buffer region (BR) and expose the upper surface of the uppermost interconnection pattern layer among the plurality of interconnection pattern layers (122), and a conductive material is filled in the opening to form a first conductive via (128).

A lower conductive pattern (137) may be formed on the first conductive via (128). The lower conductive pattern (137) may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the lower conductive pattern (137) may include aluminum (Al).

The first conductive via (128) may electrically connect the uppermost interconnection pattern layer and the lower conductive pattern (137).

In the buffer region (BR), a guard ring (140) may be defined. The guard ring (140) may extend in a horizontal direction to surround the device region (DR). The guard ring (140) may include internal interconnection (114), interconnection pattern layers (122) composed of a plurality of layers, and a lower conductive pattern (137). In the cross-sectional view, the guard ring (140) may penetrate the interconnection structure (120). The guard ring (140) may prevent cracks from occurring in the semiconductor device (100).

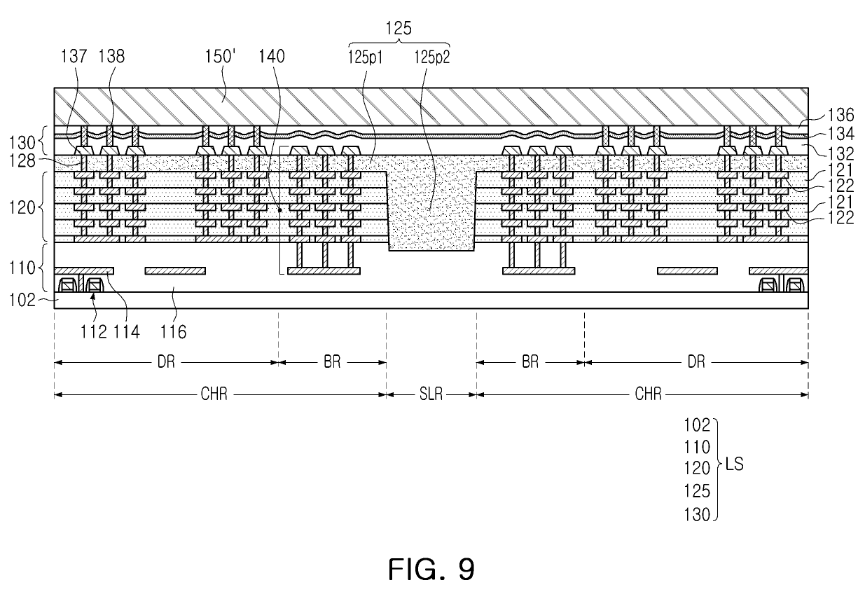

Referring to FIG. 9, a second insulating structure (130) and a conductive material layer (150’) may be formed. The semiconductor substrate (102), the device layer (110), the interconnection structure (120), and the first and second insulating structures (125, 130) may be defined as a lower structure (LS).

A second insulating structure (130) may be formed, including a first upper insulating layer (132) disposed on the first insulating structure (125) and covering the lower conductive pattern (137), a second upper insulating layer (134) on the first upper insulating layer (132), and a third upper insulating layer (136) on the second upper insulating layer (134). In an example embodiment, a portion of the second upper insulating layer (134) that vertically overlaps the lower conductive pattern (137) may protrude upward. The second upper insulating layer (134) may include a material having an etch selectivity with respect to the first upper insulating layer (132). For example, the first upper insulating layer (132) may include a high-density plasma (HDP) oxide. The second upper insulating layer (134) may include silicon nitride, silicon oxynitride, silicon carbonitride, or combinations thereof. In an example embodiment, the third upper insulating layer (136) may include silicon oxide. For example, the third upper insulating layer (136) may include TetraEthyl OrthoSilicate (TEOS). In an example embodiment, a thickness of the first upper insulating layer (132) may be greater than a thickness of the second upper insulating layer (134). In an example embodiment, a thickness of the first upper insulating layer (132) may be greater than a thickness of the third upper insulating layer (136). In an example embodiment, the thickness of the third upper insulating layer (136) may be greater than the thickness of the second upper insulating layer (134).

An opening may be formed that penetrates the second insulating structure(130) and exposes the upper surface of the lower conductive pattern(137), and a conductive material may be filled in the opening to form a second conductive via(138).

A conductive material layer(150’) may be formed on the second conductive via(138).

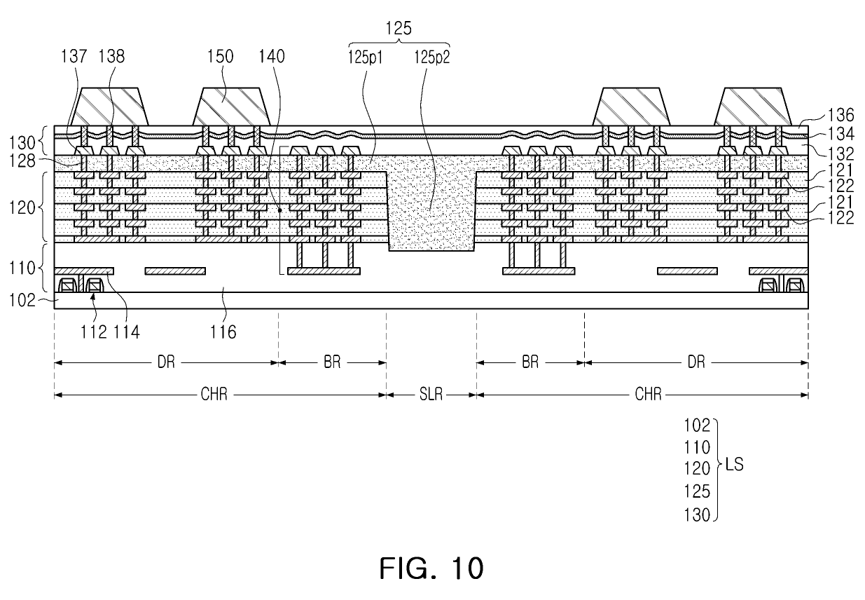

Referring to FIG. 10, the conductive material layer(150’) may be patterned to form an upper conductive pattern(150).

The upper conductive pattern(150) may configure a wiring extending in a horizontal direction and a pad connected to the wiring. The upper conductive pattern(150) may include, for example, a ground pad, a power pad, an AC pad, a data pad, and a DC pad. The ground pad may be a pad for providing a reference potential for circuit operation of the semiconductor device (100). The power pad may be a pad for supplying power for circuit operation. The AC pad may be a pad for supplying AC power to the semiconductor device (100) or receiving a signal for performing an AC test. The data pad may be a pad for input/output of logic signals or data. The DC pad may be a pad for measuring a potential level of a specific location of the semiconductor device (100).

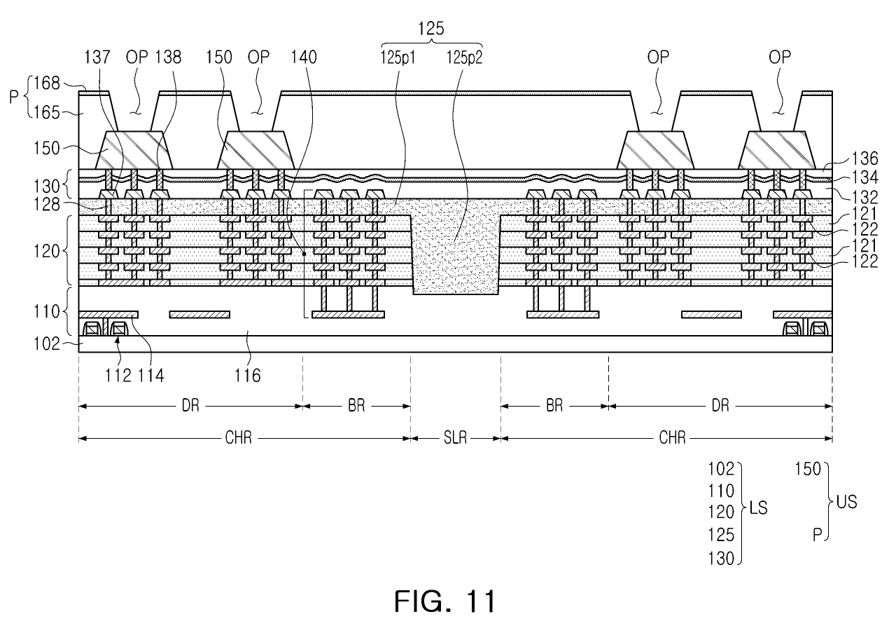

Referring to FIG. 11, a passivation structure (P) covering an upper conductive pattern (150) may be formed, and an opening (OP) exposing the upper conductive pattern (150) may be formed. The upper conductive pattern (150) and the passivation structure (P) on the lower structure (LS) may be defined as an upper structure (US).

A passivation structure (P) including a first passivation layer (165) covering an upper conductive pattern (150) on a second insulating structure (130) and a second passivation layer (168) on the first passivation layer (165) may be formed. In an example embodiment, the second passivation layer (168) may be referred to as an upper passivation layer.

The first and second passivation layers (165, 168) may include silicon oxide, silicon nitride, silicon oxynitride, or combinations thereof. For example, the first passivation layer (165) may include silicon oxide. For example, the second passivation layer (168) may include silicon nitride.

An opening (OP) penetrating the passivation structure (P) and exposing an upper surface of the upper conductive pattern (150) may be formed.

Referring to FIG. 12, a semiconductor device (100) may be formed by a dicing process.

By the dicing process, a semiconductor substrate (102), a lower interlayer insulating layer (116), a first insulating structure (125), a second insulating structure (130), a first passivation layer (165), and a second passivation layer (168) may be separated to form a semiconductor device (100).

A laser may be irradiated to the rear surface of the semiconductor substrate (102). For example, a thin film tape (not illustrated) may be attached to the semiconductor substrate (102), and a laser may be irradiated to a portion of the semiconductor substrate (102) in a scribe line region (SLR of FIG. 11). The physical characteristics of the semiconductor substrate (102) may change at the laser spot where the laser is irradiated, and for example, the physical strength of the semiconductor substrate (102) may be weakened. The thin film tape attached to the semiconductor substrate (102) may be extended in a horizontal direction so that the semiconductor substrate (102) may be separated along the center of the scribe line region (SLR of FIG. 11). Accordingly, an edge region (ER) may be defined. Alternatively, in some embodiments, the dicing process may be a process of cutting the semiconductor substrate (102) using a sawing wheel.

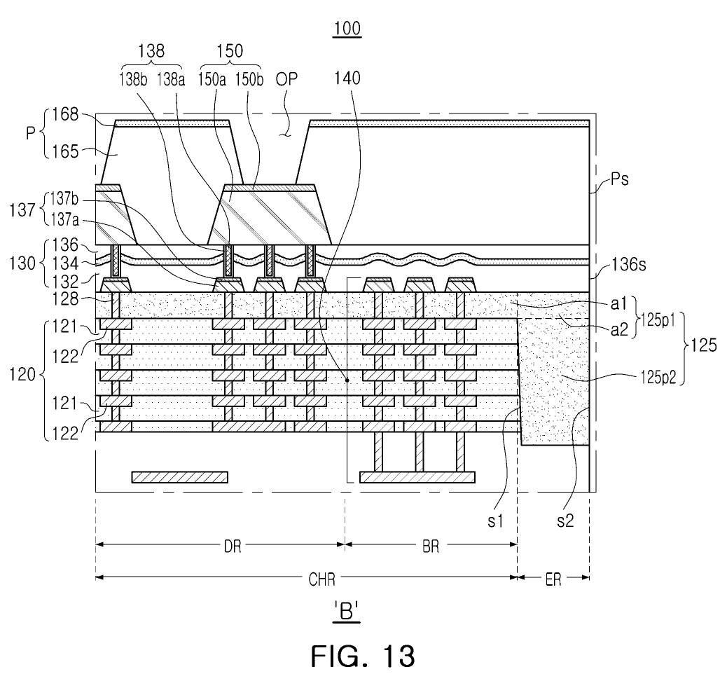

FIG. 13 is a partially enlarged view of the semiconductor device illustrated in FIG. 12. FIG. 13 may correspond to region B of FIG. 12.

Referring to FIG. 13, in an example embodiment, the lower conductive pattern (137) may include a metal layer (137a) and an anti-reflection layer (137b) on the metal layer (137a). The metal layer (137a) may include a conductive material, for example, aluminum (Al). The anti-reflection layer (137b) may be formed to protect the lower conductive pattern (137) during the process of etching the second upper insulating layer (134) and the third upper insulating layer (136) to form the second conductive via (138). The anti-reflection layer (137b) may include at least one of titanium (Ti), tantalum (Ta), tantalum nitride (TaN), titanium nitride (TiN), titanium silicon nitride (TiSiN), tungsten (W), tungsten nitride (WN), tungsten carbide (WC), and tungsten carbonitride (WCN). For example, the anti-reflection layer (137b) may include titanium nitride (TiN).

In an example embodiment, the second conductive via (138) may include a metal layer (138a) and a barrier layer (138b) covering a side surface and a lower surface of the metal layer (138a). The metal layer (138a) may include a conductive material, for example, tungsten (W). The barrier layer (138b) may include a metal nitride such as tantalum nitride (TaN), titanium nitride (TiN), or tungsten nitride (WN), for example, titanium nitride (TiN).

In an example embodiment, the upper conductive pattern (150) may include a metal layer (150a) and an anti-reflection layer (150b) covering an upper surface of the metal layer (150a). The anti-reflection layer (150b) may be formed to protect the upper conductive pattern (150) during a process of etching the first passivation layer (165) and the second passivation layer (168) to form an opening (OP). The metal layer (150a) may include a conductive material, for example, aluminum (Al). The anti-reflection layer (150b) may include at least one of titanium (Ti), tantalum (Ta), tantalum nitride (TaN), titanium nitride (TiN), titanium silicon nitride (TiSiN), tungsten (W), tungsten nitride (WN), tungsten carbide (WC), and tungsten carbonitride (WCN). For example, the anti-reflection layer (150b) may include titanium nitride (TiN).

The first insulating portion (125p1) of the first insulating structure (125) may include a first portion (a1) on the interconnection structure (120) of the device region (DR) and the buffer region (BR) and a second portion (a2) connected to the first portion (a1) and defined in an edge region (ER).

In the edge region (ER), the second insulating portion (125p2) may extend downward from the second portion (a2). The width of the second insulating portion (125p2) may decrease in the direction toward the upper surface of the semiconductor substrate (102). The second insulating portion (125p2) may include a first side (s1) facing a side surface of an interconnection structure (120) defined by a trench (‘T’ in FIG. 5) and a second side (s2) opposite to the first side (s1).

By the above dicing process, the side surface of the semiconductor device (100) may be defined. The side surface of the semiconductor device (100) may include a side surface of the lower structure (LS) and a side surface of the upper structure (US) that are aligned with each other.

At least a portion of the side surface of the lower structure (LS) may be defined by the side surface of the first insulating structure (125). For example, at least a portion of the side

surface of the lower structure (LS) may be defined by the side surface of the second portion (a2) of the first insulating portion (125p1) of the first insulating structure (125) and the second side (s2) of the second insulating portion (125p2).

A portion of the side surface of the lower structure (LS) may be defined by the side surface (130s) of the second insulating structure (130).

The side surface of the first insulating structure (125) and the side surface (130s) of the second insulating structure (130) may be aligned with each other. For example, the side surface of the second portion (a2) of the first insulating portion (125p1) of the first insulating structure (125), the second side (s2) of the second insulating portion (125p2), and the side surface (130s) of the second insulating structure (130) may be aligned with each other.

The side surface of the upper structure (US) may be defined by the side surface (Ps) of the passivation structure (P).

The side surface of the first insulating structure (125), the side surface (130s) of the second insulating structure (130), and the side surface (Ps) of the passivation structure (P) may be aligned with each other.

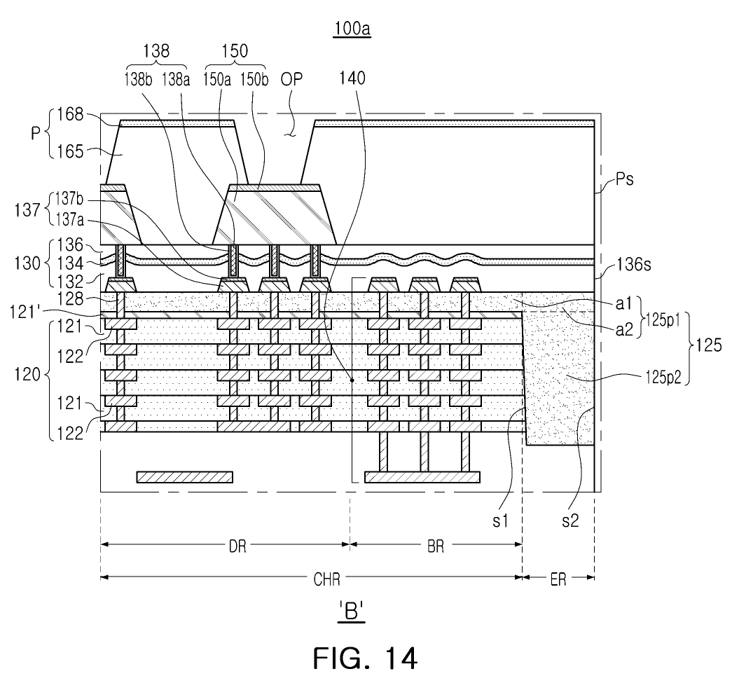

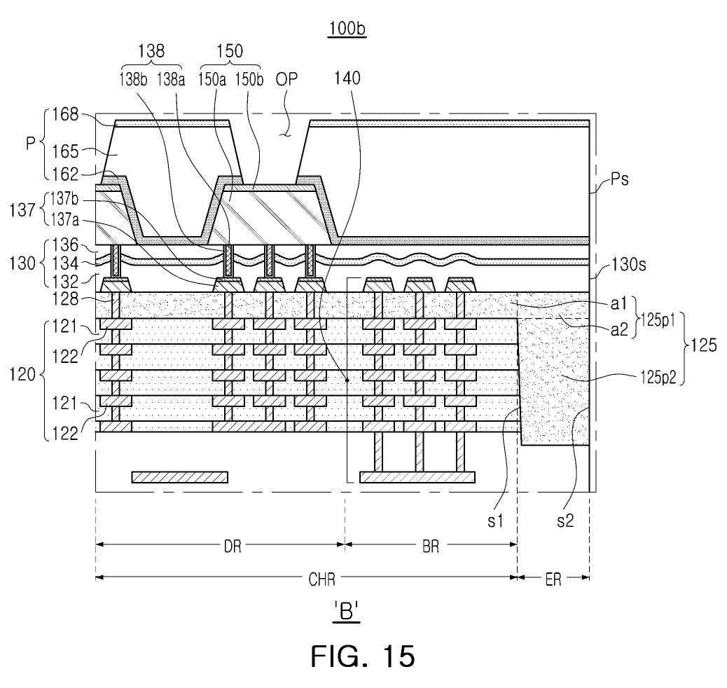

FIGS. 14 and 15 are vertical cross-sectional views of semiconductor devices according to example embodiments.

Referring to FIG. 14, the semiconductor device (100a) may be the same as or similar to that described with reference to FIGS. 12 and 13, except that it further includes an interlayer insulating layer (122’) between the uppermost interlayer insulating layer and the first insulating structure (125) among the interlayer insulating layers (121).

The interlayer insulating layer (122’) may cover the uppermost interconnection pattern layer among the plurality of interconnection pattern layers (122). The interlayer insulating layer (122’) may be for minimizing or preventing unnecessary deterioration of the uppermost interconnection pattern layer. The interlayer insulating layer (122’) may include an insulating material such as silicon oxide.

Referring to FIG. 15, the semiconductor device (100b) may be the same as or similar to that described with reference to FIGS. 12 and 13, except that it includes a passivation structure (P) further including an etch stop layer (162).

The etch stop layer (162) may conformally cover the second insulating structure (130) and the upper conductive pattern (150). In the present embodiment, an opening (OP) may be formed to penetrate the etch stop layer (162) to expose the upper surface of the upper

conductive pattern (150). The etch stop layer (162) may include silicon nitride.

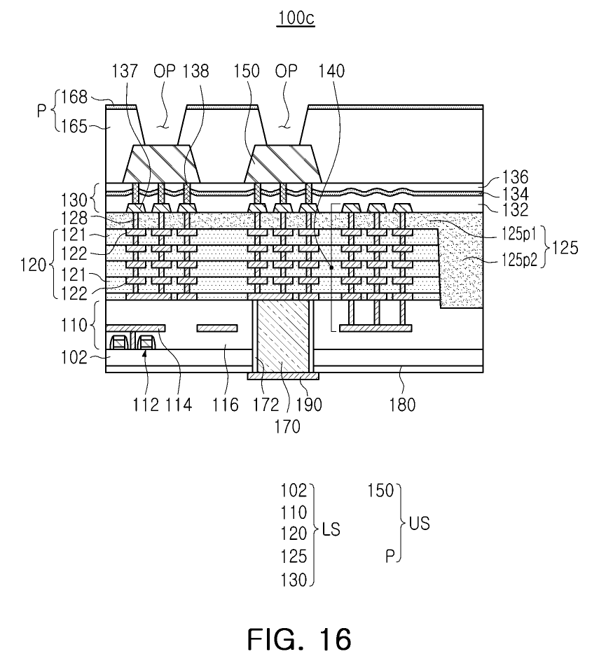

FIG. 16 is a vertical cross-sectional view of a semiconductor device according to example embodiments.

Referring to FIG. 16, the semiconductor device (100c) may further include a through-hole electrode (170), a via insulating layer (172), a lower passivation layer (180), and a via pad (190). The through-hole electrode (170) may vertically penetrate the semiconductor substrate (102) and the device layer (110) and be connected to the interconnection structure (120). The via insulating layer (172) may cover the side surface of the through-hole electrode (170). The through-hole electrode (170) may include copper (Cu), aluminum (Al), tungsten (W), nickel (Ni), titanium (Ti), titanium nitride (TiN), tantalum (Ta), tantalum nitride (TaN), gold (Au), or combinations thereof. The via insulating layer (172) may include an insulating material such as silicon oxide.

The lower passivation layer (180) may cover the lower surface of the semiconductor substrate (102), and the through-hole electrode (170) may penetrate the lower passivation layer (180). The via pad (190) may be disposed on the lower surface of the lower passivation layer (180) and connected to the through-hole electrode (170). The via pad (190) may be electrically connected to the interconnection structure (120) through the through-hole electrode (170). In some embodiments, the via pad (190) may overlap horizontally with the lower passivation layer (180), and a side surface of the via pad (190) may be in contact with the lower passivation layer (180).

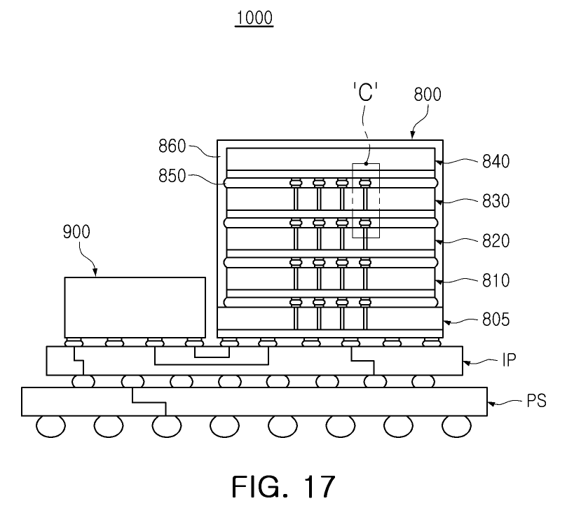

FIG. 17 is a vertical cross-sectional view of a semiconductor package including a semiconductor device according to example embodiments.

Referring to FIG. 17, the semiconductor package (1000) of the present inventive concept may be a high bandwidth memory (HBM) package. The semiconductor package (1000) may include a package substrate (PS), an interposer (IP) mounted on the package substrate (PS), a memory package (800) mounted on the interposer (IP), and a processor chip (900). The interposer (IP) may electrically connect the memory package (800) and the processor chip (900).

The memory package (800) may include a buffer chip (805), a first semiconductor device (810), a second semiconductor device (820), a third semiconductor device (830), and a fourth semiconductor device (840) that are sequentially stacked. The buffer chip (805) and the first to fourth semiconductor devices (810, 820, 830, 840) may have the same or similar

structure as the semiconductor device (100) described with reference to FIGS. 12 and 13, and may include, for example, a configuration corresponding to the first insulating structure (125). In addition, the second to fourth semiconductor devices (820, 830, 840) may include a configuration corresponding to the through-hole electrode (170), the via insulating layer (172), the lower passivation layer (180), and the via pad (190).

In an example embodiment, the buffer chip (805) may be a different type of semiconductor chip from the first to fourth semiconductor devices (810, 820, 830, and 840). For example, the buffer chip (805) may be a logic chip, and the first to fourth semiconductor devices (810, 820, 830, and 840) may be memory chips. The logic chip may include a microprocessor, an analog device, or a digital signal processor. The memory chip may include a volatile memory chip such as a Dynamic Random Access Memory (DRAM) or a Static Random Access Memory (SRAM), or a nonvolatile memory chip such as a Phase-change Random Access Memory (PRAM), a Magnetoresistive Random Access Memory (MRAM), a Ferroelectric Random Access Memory (FeRAM), or a Resistive Random Access Memory (RRAM).

The memory package (800) may further include an adhesive layer (850) and an encapsulant (860). The adhesive layer (850) may be disposed between the buffer chip (805) and the first semiconductor device (810) and between the first to fourth semiconductor devices (810, 820, 830, and 840). The adhesive layer (850) may be a Non Conductive Film (NCF) or a Non Conductive Paste (NCP). The encapsulant (860) may be a resin including epoxy or polyimide. For example, the resin may include a bisphenol-group epoxy resin, a polycyclic aromatic epoxy resin, an o-Cresol Novolac epoxy resin, a biphenyl-group epoxy resin, or a naphthalene-group epoxy resin.

The processor chip (900) may be a central processing unit (CPU), a graphics processing unit (GPU), a mobile application, or a digital signal processor (DSP) chip.

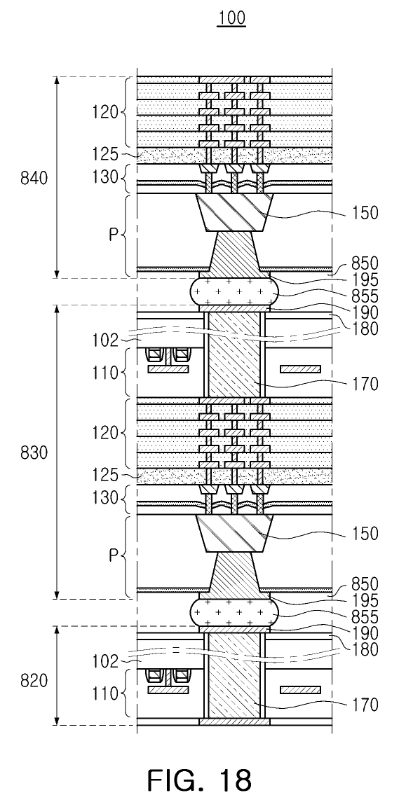

FIG. 18 is a partially enlarged view of the semiconductor package illustrated in FIG. 17. FIG. 18 may correspond to region C of FIG. 17.

Referring to FIG. 18, the memory package (800) may further include solder bumps (855) between the second semiconductor device (820) and the third semiconductor device (830) and between the third semiconductor device (830) and the fourth semiconductor device (840). The first to fourth semiconductor devices (810, 820, 830, and 840) may further include connection pads (195) connected to the upper conductive pattern (150). The connection pads

(195) may fill the openings (OP) illustrated in FIG. 16 and may come into contact with the upper conductive pattern (150). The connection pad (195) may penetrate the second passivation layer (168) and the first passivation layer (165) to contact the upper conductive pattern (150), and a part of the connection pad (195) may be on the second passivation layer (168). The bump (855) may connect the via pad (190) and the connection pad (195) between adjacent semiconductor devices (820, 830, 840). The adhesive layer (850) may cover the side surfaces of the via pad (190), the connection pad (195), and the bump (855). In an example embodiment, the bump (855) may be omitted, and the via pad (190) and the connection pad (195) may be in direct contact.

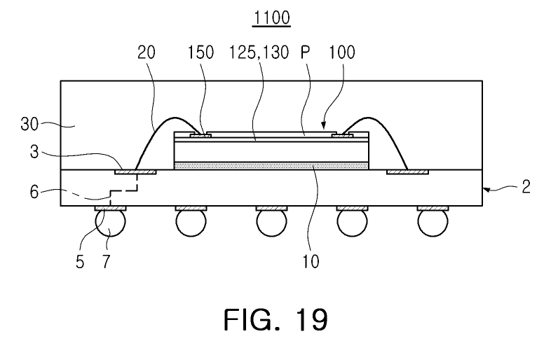

FIG. 19 is a vertical cross-sectional view of a semiconductor package including a semiconductor device according to example embodiments.

Referring to FIG. 19, the semiconductor package (1100) may include a substrate (2), an adhesive member (10), a bonding wire (20), and an encapsulant (30). The semiconductor package (1100) may also include a semiconductor device (100) on the substrate (2).

The substrate (2) may include upper pads (3), lower pads (5), internal interconnection (6), and external connection terminals (7). In an example embodiment, the substrate (2) may be a printed circuit board and may include an insulating material such as phenolic resin, epoxy resin, or prepreg. In another embodiment, the substrate (2) may be a redistribution structure in which an insulating material and a conductive material are laminated. The upper pads (3) and the lower pads (5) may be formed by forming a metal layer on a base of the substrate (2) and then patterning the metal layer.

The upper pads (3) may be disposed on the upper surface of the substrate (2) and may be electrically connected to the semiconductor device (100). The lower pads (5) may be disposed on the lower surface of the substrate (2), and the upper pads (3) may be electrically connected to the corresponding lower pads (5) by internal interconnection (6). The external connection terminals (7) may be disposed below the lower pads (5). The lower pad (5), the upper pad (3), and the wiring may include a metal such as copper (Cu). The external connection terminals (7) may be solder bumps (855).

The semiconductor device (100) may include an insulating structure (130), an upper conductive pattern (150), and a passivation structure (P), which may be identical to or similar to the components of the semiconductor device (100) illustrated in FIG. 12. For example, the first and second insulating structures (125, 130) may be disposed on the upper portion of the

semiconductor device (100). The passivation structure (P) may be disposed on the second insulating structure (130) and may protect the second insulating structure (130) from external physical impact. The upper conductive pattern (150) may be embedded in the passivation structure (P). The upper conductive pattern (150) may be connected to the upper pad (3) by a bonding wire (20).

The adhesive member (10) may be disposed between the substrate (2) and the semiconductor device (100). The adhesive member (10) may fix the semiconductor device (100) to the substrate (2). The adhesive member (10) may be a die attach film (DAF), but is not limited thereto. The encapsulant (30) may cover the substrate (2), the semiconductor device (100), and the bonding wire (20).

As set forth above, according to example embodiments, there is provided a semiconductor device with improved reliability and a semiconductor package including the same.

In detail, there are provided a semiconductor device having a side surface without a step and a semiconductor package including the same by forming a trench of a scribe line of a semiconductor substrate before forming a lower conductive pattern.

According to example embodiments, a method of manufacturing a semiconductor device, includes: forming a substrate, the substrate including a chip region and a scribe lane region surrounding the chip region; forming a device layer on the substrate; forming an interconnection structure including a plurality of interconnection pattern layers on the device layer; forming an insulating material layer on the interconnection structure; forming a trench extending downwardly through the insulating material layer of the scribe lane region and the interconnection structure; forming a first insulating structure including a first insulating portion disposed on the interconnection structure and a second insulating portion extending downwardly from the first insulating portion and filling the trench; forming a lower conductive pattern disposed on the first insulating structure; forming a second insulating structure on the lower conductive pattern; forming an upper conductive pattern on the second insulating structure; and forming a passivation structure covering the upper conductive pattern on the second insulating structure.

In addition, a method of manufacturing a semiconductor device may further include a dicing process for vertically cutting the substrate along the center of the trench.

A side surface of the first insulating structure and a side surface of the second

insulating structure may be defined by the dicing process, and the sides of each of the first and second insulating structures are aligned with each other.

In addition, in a method of manufacturing a semiconductor device, a width of the trench may decrease in a direction toward an upper surface of the substrate.

In addition, the trench may expose an upper region of the device layer.

In addition, the first insulating structure may include silicon oxide.

In addition, in a method of manufacturing a semiconductor device, the passivation structure may include a first passivation layer on the second insulating structure; and a second passivation layer on the first passivation layer.

In addition, the first passivation layer may include silicon oxide, and the second passivation layer may include silicon nitride, and a method of manufacturing a semiconductor device is provided.

In addition, the method of manufacturing a semiconductor device may further include forming a first conductive via, which extends through the first insulating portion of the first insulating structure and is connected to an uppermost interconnection pattern layer among the plurality of interconnection pattern layers, after forming the first insulating structure, and forming a second conductive via, which extends through the second insulating structure and is connected to the lower conductive pattern, after forming the second insulating structure.

In addition, in the method of manufacturing a semiconductor device, the first conductive via may electrically connect the uppermost interconnection pattern layer and the lower conductive pattern, and the second conductive via may electrically connect the lower conductive pattern and the upper conductive pattern.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a lower structure; and
an upper structure on the lower structure,
wherein the lower structure includes,
a semiconductor substrate including a chip region, and an edge region of at least one side of the chip region;
an interconnection structure disposed on the semiconductor substrate, and including a plurality of interconnection pattern layers and an insulating layer covering the plurality of interconnection pattern layers;
a first insulating structure on the interconnection structure;
a lower conductive pattern on the first insulating structure; and
a second insulating structure on the lower conductive pattern,
wherein the upper structure includes,
an upper conductive pattern on the second insulating structure; and
a passivation structure having an opening exposing at least a portion of the upper conductive pattern, on the second insulating structure,
wherein the first insulating structure includes,
a first insulating portion including a first portion disposed on an upper surface of the interconnection structure in the chip region and a second portion extending from the first portion in a horizontal direction and disposed in the edge region; and
a second insulating portion extending downwardly from the second portion of the first insulating portion in the edge region,
wherein the second insulating portion has a first side covering a side surface of the interconnection structure and a second side opposite to the first side, and
wherein at least a portion of at least one of side surfaces of the lower structure is defined by the second side of the second insulating portion.

2. The semiconductor device of claim 1, wherein the lower structure further includes:
a first conductive via penetrating the first portion of the first insulating structure and connecting an uppermost interconnection pattern layer among the plurality of interconnection pattern layers and the lower conductive pattern; and
a second conductive via penetrating the second insulating structure and connecting the lower conductive pattern and the upper conductive pattern.

3. The semiconductor device of claim 1, wherein a width of the second insulating portion of the first insulating structure decreases in a direction toward an upper surface of the semiconductor substrate.

4. The semiconductor device of claim 1, wherein a portion of the side surface of the lower structure is defined by a side surface of the second insulating structure.

5. The semiconductor device of claim 1, wherein a side surface of the upper structure is defined by a side surface of the passivation structure.

6. The semiconductor device of claim 1, wherein the passivation structure includes,
a first passivation layer on the second insulating structure; and
a second passivation layer on the first passivation layer.

7. The semiconductor device of claim 6, wherein the first passivation layer comprises silicon oxide, and
the second passivation layer comprises silicon nitride.

8. The semiconductor device of claim 6, wherein the passivation structure further comprises an etch stop layer between the upper conductive pattern and the first passivation layer.

9. The semiconductor device of claim 1, wherein the lower structure further comprises an interlayer insulating layer between the first insulating structure and the interconnection structure.

10. The semiconductor device of claim 9, wherein a thickness of the first insulating portion is greater than a thickness of the interlayer insulating layer.

11. The semiconductor device of claim 1, wherein a thickness of the first insulating structure is greater than a thickness of the interconnection structure.

12. The semiconductor device of claim 1, further comprising:
a via pad disposed below the semiconductor substrate; and
a through electrode penetrating the semiconductor substrate and electrically connecting a lowest interconnection pattern layer among the plurality of interconnection pattern layers and the via pad.

13. The semiconductor device of claim 1, wherein the first insulating structure includes silicon oxide.

14. The semiconductor device of claim 1, further comprising:
a buffer chip on the passivation structure of the upper structure; and
an encapsulant covering each of the side surfaces of the lower structure and the upper structure on the buffer chip.

15. A semiconductor device comprising:
a semiconductor substrate including a device region, a buffer region surrounding the device region, and an edge region surrounding the buffer region;
an interconnection structure disposed on the semiconductor substrate and including a plurality of interconnection pattern layers, the interconnection structure having a side surface defined between the buffer region and the edge region;
a first insulating structure on the interconnection structure, including
a first insulating portion including a portion extending in a first direction along an upper surface of the interconnection structure, in the device region, the buffer region, and the edge region, and
a second insulating portion extending downwardly from the first insulating portion and covering the side surface of the interconnection structure, in the edge region;
a lower conductive pattern on the first insulating structure;
a second insulating structure on the lower conductive pattern;
a first conductive via penetrating the first insulating structure and connecting at least a portion of the plurality of interconnection pattern layers and the lower conductive pattern;
an upper conductive pattern on the second insulating structure; and
a second conductive via penetrating the second insulating structure and connecting the lower conductive pattern and the upper conductive pattern.

16. The semiconductor device of claim 15, wherein a side surface of the second insulating portion of the first insulating structure and a side surface of the second insulating structure are aligned.

17. The semiconductor device of claim 15, further comprising a passivation structure covering the upper conductive pattern on the second insulating structure.

18. The semiconductor device of claim 17, wherein a side surface of the second insulating portion of the first insulating structure, a side surface of the second insulating structure, and a side surface of the passivation structure are aligned.

19. A semiconductor device comprising:
a lower structure; and
an upper structure on the lower structure,
wherein the lower structure includes,
a semiconductor substrate including a device region, a buffer region surrounding the device region, and an edge region surrounding the buffer region;
a device layer on the semiconductor substrate;
an interconnection structure disposed on the device layer and including a plurality of interconnection pattern layers and an insulating layer covering the plurality of interconnection pattern layers, the interconnection structure having a side surface defined between the buffer region and the edge region;
a first insulating structure on the interconnection structure;
a lower conductive pattern disposed on the first insulating structure; and
a second insulating structure on the lower conductive pattern,
wherein the upper structure includes,
an upper conductive pattern on the second insulating structure; and
a passivation structure covering the upper conductive pattern, on the second insulating structure, and having an opening exposing at least a portion of the upper conductive pattern,
wherein the first insulating structure includes,
a first insulating portion including a portion disposed above the interconnection structure, in the device region and the buffer region; and
a second insulating portion extending downwardly from at least a portion of the first insulating portion and covering the side surface of the interconnection structure, a lower end of the second insulating portion extending into the device layer, and
wherein at least a portion of a side surface of the lower structure is defined by a side surface of the first insulating structure and a side surface of the second insulating structure aligned with each other.

20. The semiconductor device of claim 19, wherein a width of the second insulating portion decreases in a direction toward an upper surface of the semiconductor substrate.
